(19) United States
(12) Patent Application Publication
(10) Pub. No.: US 2004/0216018 A1
(43) Pub. Date: Oct. 28, 2004

(54) Direct memory access controller and method

(76) Inventor: Kam Tim Cheung, Tsing Yi (HK)

Correspondence Address: FREESCALE SEMICONDUCTOR, INC., LAW DEPARTMENT, 7700 WEST PARMER LANE MD:TX32/PL02, AUSTIN, TX, 78729, US

(21) Appl. No.: 10/425,682

(22) Filed: Apr. 28, 2003

(51) Int. Cl. G01R 31/28; G06F 11/00

(52) U.S. Cl. 714/724

(57) ABSTRACT

Module verification of modules in an integrated circuit are performed with a direct memory access (DMA) unit (10) integrated in the integrated circuit. With this configuration, module verification is attainable at the semiconductor chip level and on application boards. Additionally, the DMA unit may run verification or testing of modules at full speed with internal or external clock. The DMA unit includes holding registers (112, 116, 120) and a DMA control (136) that are both coupled to a module (52, 64, 74) to be tested. The DMA controller generates source address and the required bus cycle to retrieve module information at the source address location, it stores the module information in the holding registers, and generates bus cycle based on the information stored in the holding register to run a test of the module to be tested.

### BACKGROUND OF THE INVENTION

The invention generally relates to a direct memory access (DMA) controller and method, and more particularly, to an integrated DMA controller and method for testing and verifying modules of integrated circuits.

Integrated circuits, such as microcontrollers or system on chips (SoC), are used extensively in a broad spectrum of applications, for example computers, cellular phones, home appliances, automobiles, wireless communicators, personal digital assistants, etc. Designers of such integrated circuits are incorporating and integrating therein more additional components or modules such as controllers, transmitters, transceivers, codecs, converters, memories, etc. For example, a typical SoC may include 15 to 20 distinct modules. These modules are typically designed independently and used in a variety of different applications and products. Increasing complexity of these integrated circuits has made testing and verification of each module more difficult. In particular, testing and verification of the modules on the SoCs has been a source of a critical bottleneck in SoC design. Logical and functional errors may account for high percentage of chip re-spins where the design of the chip must be modified to correct the logical and functional errors.

Testing of modules of integrated circuits has involved using Module Test Mode or Serial Test Bus Module. With respect to testing of memories in integrated circuits, built-in self-test module (BIST) logic circuitry has been used. These tests are hardware bound, and are designed at top SoC design level into the hardware of the entire layout and design of an integrated circuit, which increases the complexity of the overall design. Additionally, the BIST module tests are limited to running with an external or peripheral clock, which is typically much slower than the clock of the internal processor or the internal bus. For example, a typical personal computer central processing unit (CPU) runs at 3 GHz (internal clock), while a typical external front side bus frequency may be 333 MHz (external or peripheral clock). The tests are also limited to work in test mode only, and it is not possible to run the tests during function mode, since the test stimulus that are applied to the integrated circuit need to be synchronized with the external clock. Since the test stimulus is applied to the integrated circuit by way of the integrated circuit's input/output (IO), the speed is limited and lowered by the IO pad speed and the board capacitive loading. In module test mode, the processor is halted and the processor system bus is multiplexed through the IO pads. The Module Test Mode requires a large number of high-speed IO, and is unable to verify a module on an application board. Additionally, accurate control of the propagation delay is required because of the large number of signals involved. However, accurate control of the propagation delay is difficult to provide for because it is difficult to provide for high accuracy timing verification required in modules such as for the memory controller. Similarly, since the Serial Test Bus Module is associated with the processor, the processor is halted. A test pattern is serially shifted into the Serial Test Bus Module's internal registers, and then clocked out to the processor system bus to test the module under test. Due to the serial shifting of the Serial Test Bus Module, the test can be performed only at low speed and with an external clock. Additionally, the Serial Test Bus Module is unable to support burst access cycle and back-to-back cycle. In U.S. Pat. No. 5,668,815 a method for testing integrated or embedded memory using an integrated direct memory access (DMA) controller for performing BIST-type test is discussed. In this configuration, although performing BIST-type testing through the DMA controller is not hardware bound, the test is limited to testing only memory, and to generate “background” or predefined patterns. Additionally, the bus cycle is limited to read/write cycle, and the sequence of bus cycle is fixed. By performing read/write tests of background patterns and complements, the memory BIST is eliminated.

Thus, a need exists for an integrated DMA controller and method for testing and verifying modules and memories, embedded or external, of integrated circuits. Another need exists to port module stand alone test stimulus from a module stand alone environment, to a chip level environment, and to a post-silicon board level environment. A further need exists to shorten the design cycle and obtain a correlation between module verification, chip level verification, and post-silicon verification with a DMA unit.

### BRIEF DESCRIPTION OF THE DRAWINGS

The following detailed description of preferred embodiments of the invention will be better understood when read in conjunction with the appended drawings. For the purpose of illustrating the invention, there is shown in the drawings embodiments that are presently preferred. It should be understood, however, that the invention is not limited to the precise arrangement and instrumentalities shown. In the drawings:

FIG. 1 is a schematic block diagram of a system having a direct memory access controller circuit in accordance with an embodiment of the invention;

FIG. 2 is a schematic diagram of a direct memory access controller circuit in accordance with an embodiment of the invention; and

FIG. 3 is a flow chart of a method of an embodiment of the invention.

### DETAILED DESCRIPTION OF PREFERRED EMBODIMENTS

The detailed description set forth below in connection with the appended drawings is intended as a description of the presently preferred embodiments of the invention, and is not intended to represent the only forms in which the present invention may be practiced. It is to be understood that the same or equivalent functions may be accomplished by different embodiments that are intended to be encompassed within the spirit and scope of the invention. In the drawings, like numerals are used to indicate like elements throughout.

In embodiments of the invention, a direct memory access (DMA) controller circuit provides testing and verification of components or modules, external or embedded, of an integrated circuit, such as a microcontroller, system on chip (SoC) or the like. The components or modules include, for example, controllers, transmitters, transceivers, codecs, converters, memories, etc. With this configuration of the DMA controller of the present invention, module stand alone test stimulus can be reused from the module stand alone environment to other environments such as chip level and post-silicon board level environments, such that the time required for design and test of the integrated circuit can be reduced, while real correlation between module verification, chip level verification, and post-silicon verification can be obtained.

An aspect of the invention provides a direct memory access (DMA) unit integrated in an integrated circuit for testing a module, in which the DMA unit includes a holding register coupled to the module to be tested for storing information of the module to be tested and a DMA control block coupled with the holding register of the module. The DMA control block generates a source address and the required bus cycle to get record format data from the source address location. After the record format data is received, information of the module is stored in the holding registers of the bus interface unit for generating a bus cycle to run a test of the module to be tested at the DMA controller, the bus cycle and test based on the information stored in the holding register.

Another embodiment of the invention includes a channel array controller for controlling multiple DMA transfers in the DMA unit of the integrated circuit. The information of the module may also be a control signal, address signal and data signal information. The information may be converted from a verification language format into a record format. The DMA controller source address signals and control signals may be generated according to the DMA internal programmed register settings. Additionally, the clock can be determined to run the DMA control to generate the address source, and test the module to be tested.

Yet another embodiment of the invention provides a method for testing a module with a DMA unit integrated in an integrated circuit. The method includes generating in the DMA unit a source address, and the required bus cycle; requesting information of the module from the source address location; storing the information of the module in the holding registers in the DMA unit, the holding registers coupled to the DMA controller and module to be tested; and generating a bus cycle to run a test of the module to be tested at the DMA controller. The bus cycle and the test are based on the information stored in the holding register.

Accordingly, one embodiment of the invention provides initializing the DMA controller prior to generating the source address and the required bus cycle in the DMA controller. Another embodiment provides converting the information of the module from a verification language format into a record format.

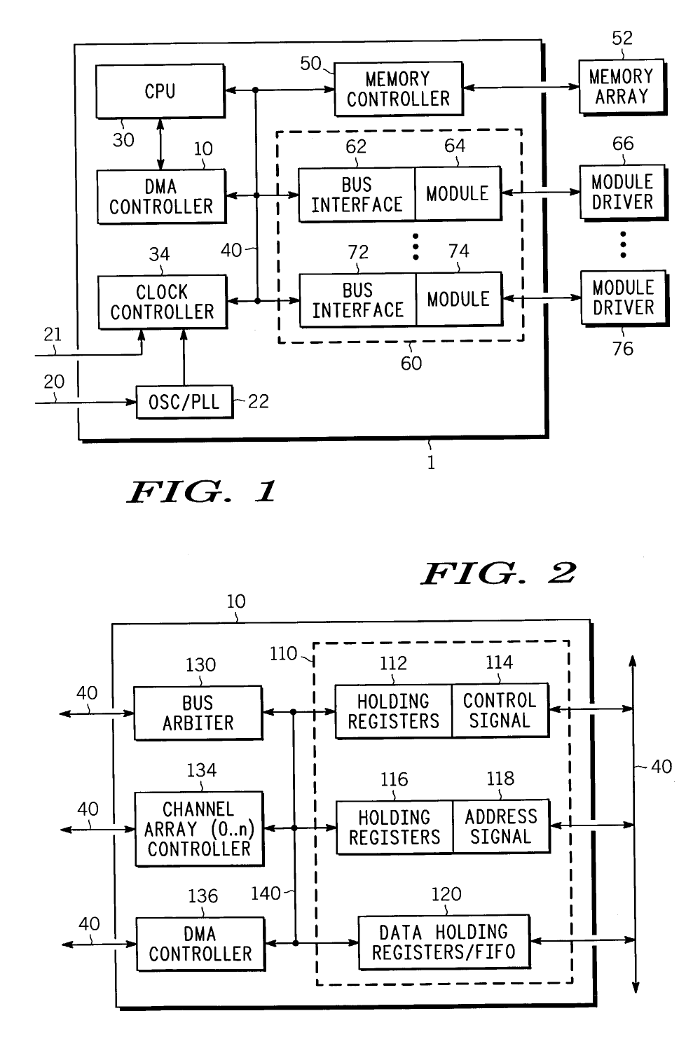

Referring now to FIG. 1, a schematic diagram is shown of an integrated circuit, such as a microcontroller or SoC 1. In this embodiment, the integrated circuit is formed on a semiconductor substrate. The microcontroller or SoC 1 shown includes a DMA controller 10 that is in direct communication with a central processing unit (CPU) 30. The integrated circuit further includes a memory controller 50 and any number of module units 60. Each module unit 60 includes a bus interface 62, 72 and a module 64, 74 to be verified. A memory array 52 and module drivers 66, 76 are in respective communication with the memory controller 50 and the appropriate module 64, 74 in the module unit 60. A CPU processor system bus 40 interconnects each CPU 30, DMA controller 10, memory controller 50, and each bus interface 62, 72 of each module 64, 74 of the module unit 60. A clock controller 34 provides an internal clock to the DMA controller 10 via an oscillator or PLL 22 by a path 20, and provides an external clock to the DMA controller 10 via a path 21. Examples of the memory controller 50 may be a FLASH controller, SRAM controller, SDRAM controller or the like, for FLASH, SRAM, SDRAM or the like memory. The modules 60 can be synchronous serial interface (SSI), universal asynchronous receive and transmit (UART), universal serial bus (USB) or the like communication controller, which may be used for various types of communication channels. Of course, it will be appreciated that the modules 60 may also be timers, PWM, RTC or the like, which may be used for general purpose timing and counting.

FIG. 2 is a schematic diagram the DMA controller 10 in accordance with an embodiment of the invention. The DMA controller 10 includes a bus arbiter 130, channel array (0 . . . n) controller 134, and DMA control 136 that are in communication with the CPU processor system bus 40. The DMA controller 10 usually supports more than one data transfer or one channel, as represented by the channel array controller 134. Each channel contains registers to specify source address, destination address, type of transfer, burst length, priority, etc. for that channel. For example, it will be appreciated that a DMA that has four channels can support four DMA transfers concurrently. The channel array controller 134 receives DMA requests from the CPU 30 or elsewhere. For example, DMA requests may be generated by the DMA controller 10 according to the DMA controller's internal programmed registers or the DMA controller 10 may receive an external request. Control signals, address signals, and data signals are generated at a bus interface unit 110. The bus interface unit 110 includes holding registers 112, 116, control signal and address signal generators 114, 118. Data signal information is held at data holding registers or first-in-first-out (FIFO) 120. The bus interface unit 110 is in communication with the CPU processor system bus 40. Each element including the bus arbiter 130, channel array controller 134, control signal and address signal generators 114, 118, and data holding registers/FIFO 120 are interconnected via a DMA controller internal bus 140.

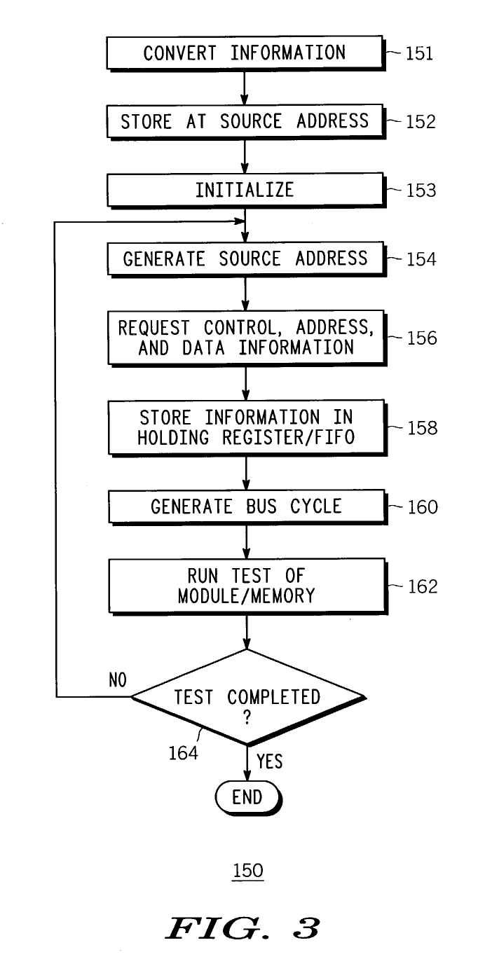

In operation, with reference to a method 150 shown in FIG. 3 accordance with an embodiment of the invention, the control signal information, address signal information, and data signal information are converted at a step 151 from module stand alone test stimulus, for example, digital simulator format including any verification language, for example VERILOG™ tasks, and stored in step 152 at the source addresses into a record format, for example, memory array format. After an initialization step 153, at step 154 the DMA controller 10 generates a source address. The bus control signal information is generated at the control signal generator 114, address signal information is generated at address signal generator 118, and data signal information is generated at data holding registers/FIFO 120 to form the required bus cycle. The source address and the required bus cycle are generated according to the DMA internal programmed register settings. In this manner, at step 156 the DMA controller 10 can advantageously make use of either the external or internal clock to generate source addresses and required bus cycles, and make use of the clock to request the control, address, and data information from the source addresses via the memory controller 50 or any verified module 60, 64, 74. Selection of internal and external clock can be done by software program or by hardware. For example, in software, the microcontroller or SoC 1 has clock select control where the CPU 30 writes in the selected clock in the internal register, and in hardware the clock select may be determined by an I/O pin configuration with dedicated pin combinations. The control, address, and data information is then stored at step 158 in the respective data holding registers or FIFO 112, 116, 120, to then generate the bus cycles at step 160, to run and test the module to be verified at the selected clock rate in step 162. An example of the of module level test showing a MOTOROLA™ MC68000 CPU read task and a write task that are converted into two records, a read cycle is indicated by “0” in the read/write (“r/w”) column under control information signal at the first record, as shown in Table 1, where “fc[2:0]” is the function code signals, “r/w” is the read write signal, “uds” is the upper data strobe signal, “lds” is the lower data strobe signal, “address” is the address bus, and “data” is the data bus.

TABLE 1

| | | |
|---|---|---|
| Control | Address | Data |

| Fc[2:0] | r/w | uds | Ids | A[31.0] | D[15.0] |
|---|---|---|---|---|---|
| 110 | 0 | 0 | 0 | FFFFFF08 | AAAA |
| 110 | 1 | 0 | 0 | FFFFFF08 | AAAA |

The module stand alone test stimulus is a processor system bus representation. The module stand-alone test stimulus represented by example in Table 1, contains address, control, and data information that is converted from its verification language format into a record. Another example is shown in Table 2, where the signal is represented at “cmd” “A0” of control signal information, and where “000000000000000000000000” indicates that the test is completed, as checked at step 164.

TABLE 2

| Cmd | Control | Address | Data | |
|---|---|---|---|---|
| [7:0] | AHB control signals [23:0] | HADDR [31:0] | HWDATA | HRDATA |
| 90 | 000100010000100100011100 | 00221004 | 55555555 | 00000000 |
| 80 | 000100010000100100011000 | 00221004 | 00000000 | 55555555 |
| 90 | 000000000000000000010100 | | | |
| A0 | 000000000000000000000000 | | | |

In Table 2, “cmd” is a command to guide the DMA operations, “control” is the AHB control signals, “address” is the address bus, “HWDATA” is the write data bus, and “HRDATA” is the read data bus. The CPU system bus in Table 1 is a MOTOROLA™ MC68000 CPU system bus, while the CPU system bus in Table 2 refers to the ARM™ AHB CPU system bus.

With this record, the DMA controller 10 may generate the type of bus access cycles, destination addresses, and data according to the data read from the source addresses, and generate any type of bus access cycle in any sequence. The types of bus access cycles include, for example, any privilege cycle, endianess cycle, back-to-back cycle, burst cycle, and illegal bus cycles. Since the DMA controller 10 generates bus cycles according to the record read from the source address, the bus cycle may be any type of bus cycle and the sequence of these bus cycles are generated according to the record. For example, the bus cycle may be a burst write cycle followed by a burst write cycle to the same address that cannot be generated by the CPU 30. If the test is completed, as determined at step 164, then the method 150 ends. Alternatively, if the test is not completed, the method 150 is repeated from generating the source address step 154.

The DMA controller 10 may be used to test and verify a variety of modules. Such a module is a USB module that can be verified using the DMA controller 10. With reference to FIGS. 2 and 3, the USB module stand-alone test stimulus is converted at step 151 into the record, then at step 152 the record is stored at external memory. The DMA controller 10 is programmed with the source address that is the start or the initial part of the record signal stored in step 152 in the memory location. Then, at step 154 the DMA generates the source address, and at step 156 reads data from the external memory via the memory controller 50. The test may contain the initialization of the USB, and then a transmission of a short data packet. Then, the DMA controller 10, at step 160, may generate a write cycle to write the USB internal register to initialize the USB. Then the sequence is repeated from step 154, until completion of the data packet transmission. At step 160, read cycle is generated to read the USB internal status register and at step 162 check if the transmission is successful or not.

In another example, the record is stored at a computer. The DMA controller 10 can access the record using the on-chip universal asynchronous receive and transmit (UART) with the source address being the UART internal register location. The record can be downloaded via the UART connection between the chip 1 and the computer.

With this configuration, the amount of time for verification of the design of integrated circuits may be reduced, thus saving costs and allowing a greater amount of time to be devoted to the design of integrated circuitry. Direct porting of module verification is attainable at the semiconductor chip level, and module or component verification and correlation can be achieved on application boards with an embodiment of the invention. Additionally, the DMA controller 10 may run verification or testing of modules at full speed with internal, such as PLL, or external clock, the DMA controller 10 may run independent of the number and speed of input/output (IOs), and the DMA controller 10 may verify and test external memory bus frequency, configuration, and loading. Advantageously, the DMA controller 10 does not need to be designed into the design of an entire integrated circuit such as a microcontroller, in so-called top-level integration, as the functions of the DMA controller are independent from other components in the circuitry. No additional test pin is required if function mode is to be used. However, if test mode is to be used, then a test pin may be required to switch the chip into test mode. Another advantage of direct porting is that a simple script can perform the conversion. Additionally, the module stand-alone test stimulus may be used for a variety of applications and systems. For example various configurations and implementations of the DMA controller or method can be envisaged, for example, a timer may be used by the SDRAM controller, and the SDRAM controller may be used by an application processor. The application processor may be used with another RF communication controller to form a mobile phone. Additionally, an example includes, three identical UARTs implemented within a single communication controller. The DMA controller of an embodiment of the invention also enables verification of modules and components at each level of integration, such as at module, chip, post-silicon verification on application development system (ADS) board, post-silicon production test on automatic test equipment (ATE) board, post-silicon debugging final products. Advantageously, verification tests may be downloaded via any peripheral unit or memory. Additionally, there is no requirement to convert stand-alone tests into CPU test programs, which can save design cycle time. Further, randomization of test sequences can achieve maximum coverage. The module stand-alone test can be written in a random sequence. For example, the generated random test module pattern may be recorded to the DMA controller, since without the DMA controller, the CPU would be unable to perform randomization. In this manner, the randomization may be performed at chip SoC level and post-silicon level.

The DMA controller 10 is also configured in an embodiment such that the DMA controller has full controllability of the CPU or system bus, to accurately assert bus cycles at a specified clock cycle for critical tests, such as for example simultaneous FIFO access. Additionally, the DMA controller 10 can easily verify other bus masters and memory controllers, for example, graphic controller, multi-media accelerator or the like. Due to the ability to use the external or internal clock, the simulation or verification may be run efficiently using and taking advantage of the full capabilities of the system. Additionally, the DMA controller 10 can make use of the internal DMA bus master capability to obtain full controllability of the CPU or system bus to verify modules and the CPU need not to be halted. The DMA controller 10 can work when the chip is in either function or test mode. The DMA controller 10 also can work independent of the external memory bus frequency, configuration and loading, and can provide correlation between simulation and application.

The detailed description provides preferred exemplary embodiments only and is not intended to limit the scope, applicability or configuration of the invention. Rather, the detailed description of the preferred exemplary embodiments provides those skilled in the art with an enabling description for implementing the preferred exemplary embodiment of the invention. It should be understood that various changes can be made in the function and arrangement of elements without departing from the scope of the invention as set forth in the appended claims.

1. A direct memory access (DMA) controller integrated in an integrated circuit for testing a module, the DMA controller comprising:
a holding register coupled to the module to be tested for storing information of the module to be tested; and
a DMA control coupled with the holding register of the module and in communication with the module, the DMA control for generating a source address of the module, and generating a bus cycle to run a test of the module to be tested, wherein the bus cycle and test are based on the information stored in the holding register.

2. The DMA controller as claimed in claim 1, further comprising a channel array controller for controlling multiple DMA transfers in the DMA controller of the integrated circuit.

3. The DMA controller as claimed in claim 1, wherein the information of the module is control signal, address signal and data signal information.

4. The DMA controller as claimed in claim 3, wherein the DMA controller source address signals and control signals are generated according to internal programmed register settings of the DMA controller.

5. The DMA controller as claimed in claim 1, further comprising a clock controller coupled to the DMA control, wherein the DMA control receives a clock signal from the clock controller, wherein the clock signal is one of an internal clock signal and an external clock signal, and the DMA control operates in accordance with the clock signal to generate the source address and test the module to be tested.

6. The DMA controller as claimed in claim 5, wherein the received clock signal is the internal clock signal.

7. The DMA controller as claimed in claim 1, wherein the module is a memory.

8. The DMA controller as claimed in claim 1, wherein the module is a communication controller.

9. A method for testing a module with a direct memory access (DMA) controller, wherein the module and the DMA controller are integrated in an integrated circuit, the method comprising the steps of:
generating in a DMA control of the DMA controller a source address, wherein the DMA control is in communication with the module to be tested;
requesting information of the module from the source address location;
storing the information of the module in a holding register in the DMA controller, the holding register coupled to the DMA control and the module to be tested; and
generating bus cycles at the DMA control to run a test of the module to be tested, wherein the bus cycles and the test are based on the information stored in the holding register.

10. The method for testing a module of claim 9, further comprising the step of initializing the source address prior to generating the source address of the module in the DMA control.

11. The method for testing a module of claim 10, further comprising the step of converting the information of the module from a verification language format into a record format.
